(19) United States
(12) Patent Application Publication
(10) Pub. No.: US 2025/0262672 A1
(43) Pub. Date: Aug. 21, 2025

(54) METHOD OF PREDICTING OPTIMAL PROCESS CONDITIONS IN LASER POWDER BED FUSION

(71) Applicant: POSTECH RESEARCH AND BUSINESS DEVELOPMENT FOUNDATION, Pohang-si (KR)

(72) Inventors: Byeong Joo LEE, Pohang-si (KR); Jae Min WANG, Pohang-si (KR); Hyoung Seop KIM, Pohang-si (KR); Sang Guk JEONG, Pohang-si (KR); Eun Seong KIM, Pohang-si (KR)

(21) Appl. No.: 18/822,697

(22) Filed: Sep. 3, 2024

(30) Foreign Application Priority Data
Feb. 19, 2024 (KR) 10-2024-0023559

(51) Int. Cl. B22F 12/90; B22F 10/28; B33Y 10/00; B33Y 50/02

(52) U.S. Cl. CPC B22F 12/90; B22F 10/28; B33Y 10/00; B33Y 50/02

(57) ABSTRACT

Disclosed herein is a method of optimizing and predicting process conditions used in laser powder bed fusion. Data consisting of the properties of alloy powders and the process conditions are normalized, and the relative density, which is a target value, is transformed to a sigmoid function value. Preprocessed data is used in training of a machine learning model. This process allows for the prediction of sets of optimal process conditions for metal powders not used in machine learning.

### CROSS-REFERENCE TO RELATED PATENT APPLICATION

This application claims the benefit of Korean Patent Application No. 10-2024-0023559, filed on Feb. 19, 2024, in the Korean Intellectual Property Office, the disclosure of which is incorporated herein in its entirety by reference.

### BACKGROUND OF THE INVENTION

### 1. Field of the Invention

The present invention relates to a high-precision additive manufacturing (AM) method to produce metal parts, and more specifically, to a method of predicting optimal process conditions through machine learning in the field of laser powder bed fusion.

### 2. Description of the Related Art

Laser powder bed fusion (L-PBF), also known as selective laser melting, is a high-precision additive manufacturing methods to produce metal parts that have superior mechanical properties. L-PBF uses a laser to additively manufacture different types of metal layers. For example, a layer of powdered metal is spread on a bed, then a laser is used to fuse the powder layer, and the molten layer is rapidly cooled to form one layer. Subsequently, another thin layer of powered metal is spread over it, followed by repeated laser melting and cooling. This process is repeated until the desired metal part is obtained.

Due to its unique process characteristics, the above-mentioned L-PBF has been applied to the production of precision parts used in industries such as aerospace, automotive, healthcare, etc., and the optimization of the process for new alloy powders is required. Moreover, manufacturers of equipment for conducting the L-PBF process provide optimal process conditions for each metal powder. These process conditions were obtained through repeated trial and error, and although there have been many studies aimed at achieve the optimization of the process through machine learning, they have predominantly focused on the optimization of one type of powder.

Generally, metal powders in the form of alloys have varying properties or characteristics, and thus it is necessary to apply process conditions suitable for the properties of a metal powder; otherwise, defects may occur in the manufactured metal parts. Therefore, it is necessary to derive optimal process conditions separately for each type of metal powder. For instance, if an improvement in production speed or precision of metal parts is demanded by the user, various optimal process conditions are needed for the same type of metal powder. In other words, it is highly impractical to identify these process conditions through trial and error repeatedly in an environment where various process conditions are required.

To address the aforementioned issues, attempts have been made to optimize the process conditions using machine learning. U.S. Patent Application Publication No. 2021-0405613 discloses a method for prediction of porosity appearance generated during L-PBF. This is accomplished through training a machine learning model, where porosity data is obtained through imaging. When process conditions are input into the learned model, it provides a porosity map to the user.

However, the aforementioned patent has limitations as it is applicable to only one type of metal powder, requiring the user to input process conditions for a specific metal powder. In other words, it remains silent on the area of providing optimal process conditions for various metal powders.

### SUMMARY OF THE INVENTION

The present invention has been made in an effort to solve the above-described problems associated with prior art, and an object of the present invention is to predict optimal process conditions for various metal powders, regardless of whether they are included in the training of a machine learning model.

To achieve the above-mentioned object, the present invention provides a method of predicting optimal process conditions, comprising the steps of: training a machine learning model based on properties of a metal powder, process conditions, and relative density; and predicting a set of process conditions with a high relative density for a specific metal powder using the trained machine learning model and random search.

The above-mentioned object of the present invention can be achieved by providing a method of predicting optimal process conditions, comprising the steps of: training a machine learning model based on properties of a metal powder, process conditions, and relative density; and predicting a set of process conditions with a high relative density for a metal powder, which is not used in the training of the machine learning model, using the trained machine learning model and random search.

According to the present invention as described above, the properties of the metal powder and the process conditions serve as input data, and the correlation between them and the relative density, which is a target value, is determined through the training of the machine learning model. During this process, the properties of the metal powder and the process conditions are normalized, and the relative density is transformed to a sigmoid function value and used in the training of the machine learning model. Moreover, the user can input the properties of a specific powder that he or she wishes to predict, enabling the prediction of process conditions with a high relative density. This allows for the prediction of sets of optimal process conditions even for powders with compositions that were not used in the training of the machine learning model. In other words, the user can input the properties of the powder that he or she intends to use, fixed values of process conditions, etc. to obtain a set of optimal process conditions through the pre-trained machine learning model. This allows for the prediction of sets of optimal process conditions with high relative densities across various alloys, leading to a significant reduction in time and cost spent on optimization for each type of alloy.

### BRIEF DESCRIPTION OF THE DRAWINGS

The above and other features and advantages of the present invention will become more apparent by describing in detail exemplary embodiments thereof with reference to the attached drawings in which:

FIG. 1 is a flowchart illustrating the process of deriving optimal process conditions for alloy powder according to a preferred embodiment of the present invention;

FIG. 2 is a flowchart illustrating the process of training a machine learning model of FIG. 1 according to a preferred embodiment of the present invention;

FIG. 3 is a graph illustrating a sigmoid function used for preprocessing of the relative density according to a preferred embodiment of the present invention;

FIG. 4 is a flowchart illustrating a method of predicting process conditions with a high relative density for a specific powder of FIG. 1 according to a preferred embodiment of the present invention;

FIG. 5 is a table showing the sets of process conditions predicted in Prediction Example 1 of the present invention and the relative densities measured through experiments;

FIG. 6 is a table showing the sets of process conditions predicted in Prediction Example 2 of the present invention and the relative densities measured through experiments; and

FIG. 7 is a table showing the sets of process conditions predicted in Prediction Example 3 of the present invention and the relative density measured through experiments.

### DETAILED DESCRIPTION OF THE INVENTION

As the present invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the drawings, like reference numerals have been used throughout to designate like elements.

Unless defined otherwise, all terms used herein including technical or scientific terms have the same meaning as those generally understood by those skilled in the art to which the present invention pertains. It will be further understood that terms defined in dictionaries that are commonly used should be interpreted as having meanings that are consistent with their meanings in the context of the relevant art and should not be interpreted as having ideal or excessively formal meanings unless clearly defined in the present application.

Hereinafter, preferred embodiments of the present invention will be described in more detail with reference to the accompanying drawings.

### Embodiments

In the present invention, L-PBF is used to manufacture metal parts, and during L-PBF, optimal process conditions for various types of metal powders are predicted. Relative density based on the optimal process conditions is a standard for evaluating the quality of the resulting metal parts. In other words, a low relative density means that a large number of pores or voids have occurred in the metal part, and these pores or voids act as the starting point of cracks in the metal part with a stacked structure and reduce the mechanical properties of the metal part. Therefore, it is desirable for metal parts to have a high relative density.

The present invention provides a method for optimization of process conditions based on machine learning, which can be used for various alloy powders. The machine learning model of the present invention in which the properties of a specific metal powder and the process conditions for the metal powder are combined predict the relative density of the resulting metal part. To this end, the machine learning model may receive a sufficiently large amount of data as input to learn the interaction between the properties of the metal powder and the process conditions.

In the present invention, the properties of the metal powder refer to the material properties of the powder made of alloy, such as reflectance, thermal conductivity, specific heat capacity, mass density, and melting point, and the process conditions include laser power, scan speed, hatch distance, and layer thickness.

In the present invention, the correlation between the properties of the metal powder, the process conditions, and the relative density can be established through the training of the machine learning model. Moreover, when the properties of the metal powder selected by the user are input, the process conditions and the relative density can be derived through a random search, and the process conditions for the metal powder input by the user and having the highest relative density are derived through an optimization process.

In particular, multiple sets of process conditions may be provided for the metal powder input by the user. Furthermore, each set of process conditions is provided with a target relative density associated with it. The set of process conditions consists of the above-mentioned laser power, scan speed, hatch distance, and layer thickness. That is, the relative density based on the set of process conditions for a selected metal powder is provided.

FIG. 1 is a flowchart illustrating the process of deriving optimal process conditions for alloy powder according to a preferred embodiment of the present invention.

Referring to FIG. 1, the method for deriving optimal process conditions of the present invention may comprise the step (S100) of training a machine learning model and the step (S200) of predicting process conditions with a high relative density for a specific metal powder.

First, the training of the machine learning model may be performed, and the target relative density may be learned from various properties of metal powders and process conditions as inputs.

During the training of the machine learning model in the present invention, the properties of metal powders and the process conditions serve as input, and the relative density of the resulting metal part serves as a target value. Through the training of the machine learning model, the correlation between the properties of metal powders, the process conditions and the relative density may be learned through regression analysis. Moreover, the optimal process conditions can be derived using a trained machine learning model. To derive or predict the optimal process conditions, the user may input the properties of the metal powder and derive the process conditions through a random search.

The derived process conditions may be input into the trained machine learning model along with the properties of the metal powder input by the user, and the relative density may be derived. The input of the properties of the metal powder and the process conditions into the machine learning model and the derivation of the relative density through the random search may be performed until there is no change in the relative density based on the optimal process conditions.

First, the step of training a machine learning model may include the steps of collecting a variety of information about the powder and performing data preprocessing on the collected information. Then, the training of the machine learning model may be performed using the preprocessed data.

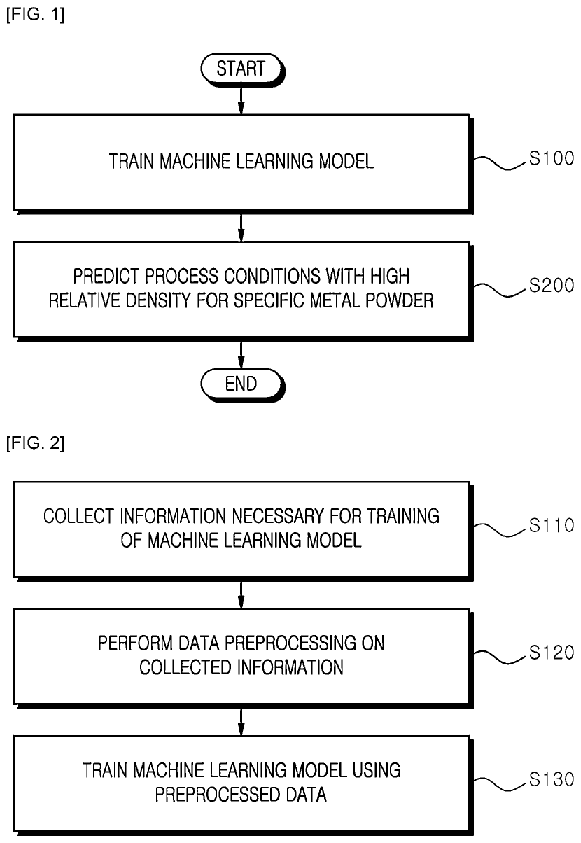

FIG. 2 is a flowchart illustrating the process of training the machine learning model of FIG. 1 according to a preferred embodiment of the present invention.

Referring to FIG. 2, information necessary for the training of the machine learning model may be collected (S110).

The information may include the properties of the metal powder, the process conditions and the relative densities. That is, the information consists of at least one of the process conditions, which are associated with the properties of one type of metal powder, and the relative density based on the process conditions, and the collected information may include the process conditions and the relative densities for various types of metal powders. However, the information necessary for training may not include the composition of the metal powder, but include the properties of the metal powder, the process conditions associated with these properties, and the relative density of the products associated with the properties.

The properties of the metal powder may include its reflectance, thermal conductivity, specific heat capacity, melting point, and density, and the process conditions may include laser power, laser scan speed, hatch distance, and layer thickness. However, a designer for training the machine learning model can change the properties of the metal powder in various ways, and the process conditions can also be added to or changed from the above.

The properties of metal parts manufactured using L-PBF are greatly influenced by the proposed process conditions. An inappropriate combination of the process conditions may result in the formation of pores or the lack of fusion, leading to the formation of voids within the metal part. In particular, the voids or pores act as the starting point of cracks in the metal part with a stacked structure. In other words, a high porosity within the metal part reduces the mechanical properties of the metal part.

In particular, the relative density of the metal part may vary depending on the process conditions, and even if the same material is used, the relative density varies depending on the influence of the process conditions. For example, the laser energy density can be defined by the following Equation 1:

$${E}_{d} = \frac{P}{v \cdot h \cdot t} \qquad [ Equation 1 ]$$

In Equation 1, Ed represents the laser energy density (J/mm³), P represents the laser power (W), v represents the scan speed (mm/s), h represents the hatch distance (mm), and t represents the layer thickness (mm).

In Equation 1, an insufficient laser energy density may lead to the formation of pores due to inadequate fusion of the metal material, whereas an excessive laser energy density may also lead to the formation of pores due to vaporization. Therefore, the process conditions for achieving a high relative density need to be adjusted according to the metal powder used.

Moreover, even if the same process conditions are applied, the relative density may vary depending on the properties of the metal powder used as the material.

The properties of the metal powder also have a significant impact on the relative density. In other words, if the thermal conductivity decreases, the relative density increases. This means that a low thermal conductivity may result in the concentration of energy in an area where the laser is irradiated, leading to a uniform fusion. If the thermal conductivity increases, the laser energy density required for uniform fusion also increases.

As mentioned above, the process conditions and the properties of the metal powder affect the relative density.

In the present invention, the process conditions, the properties of the metal powder and the relative densities may be collected with reference to previous research results and numerous papers.

In particular, the relative density can be measured through image analysis without using the conventional Archimedes method. The image analysis is used to derive the relative density based on the area of pores appearing through the cut surface of the metal part. For example, the relative density follows Equation 2 below:

$$Relative density = ( 100 - Porosity ) \% \qquad [ Equation 2 ]$$

Subsequently, data preprocessing may be performed to normalize the collected properties of the metal powder and the process conditions using mean and standard deviation and convert the target relative density to a sigmoid function value using a sigmoid function (S120).

In this embodiment, the data preprocessing refers to the process of normalizing the process conditions and the properties of the metal powder using the mean and standard deviation and converting the relative density to a sigmoid function value. That is, the relative densities, the process conditions and the properties of the metal powder of the metal parts manufactured under the process conditions from the metal powder with the corresponding properties may be investigated, and these relative densities, the process conditions and the properties of the metal powder may be preprocessed with normal distribution and sigmoid function values.

The sigmoid function for the relative density follows Equation 3 below:

$$y = \frac{1}{1 + {e}^{- ( x - {x}_{s t} )}} \qquad [ Equation 3 ]$$

In Equation 3, y represents the sigmoid function value preprocessed with the sigmoid function for the relative density, x represents the relative density, and xₛₜ represents the reference value of the relative density. The reference value of the relative density is named the reference relative density.

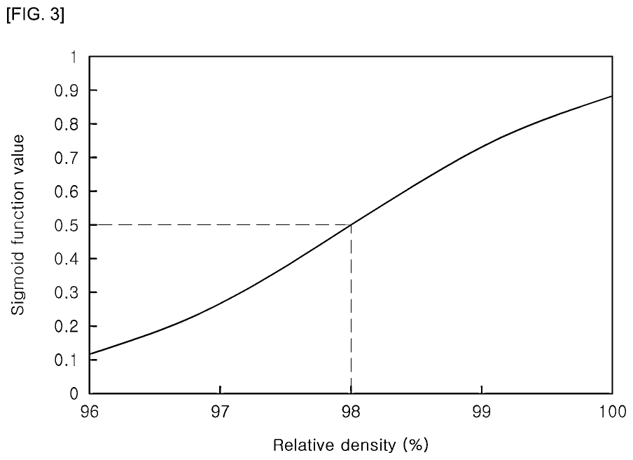

FIG. 3 is a graph illustrating a sigmoid function used for preprocessing of the relative density according to a preferred embodiment of the present invention.

Referring to FIG. 3, in the case where the reference relative density is set to 98%, if the relative density is 98%, the sigmoid function value is 0.5; if the relative density is less than 98%, the sigmoid function value approaches 0; and if the relative density exceeds 98%, the sigmoid function value approaches 1. In other words, if the sigmoid function value is approaches 1, the metal part has a high relative density exceeding 98%.

Referring again to FIG. 2, the machine learning model may be trained using the preprocessed data (S130).

The normalized properties of the metal powder and the detailed process conditions may be input into the machine learning model, and it may be investigated how the relative densities of the manufactured metal part are distributed around the reference relative density through machine learning. This is a type of regression analysis, and the correlation between the properties of the metal powder and the process conditions, which are input values, and the relative density, which is target value, may be obtained through normal distribution and using a sigmoid function.

The machine learning model of the present invention is a regression model that converts a target value to a sigmoid function value and then predicts the converted sigmoid function value. This is different from the existing regression model, which directly predicts the target value, and the classification model, which predicts the target value converted by binary.

In terms of the data structure of the present invention, the regression model tends to underestimate the predicted value when the target value exceeds the reference value, and the classification model tends to overestimate the predicted value when the target value exceeds the reference value. However, the machine learning model of the present invention alleviates the problems of the two existing models by normalizing the target value using a sigmoid function.

During the training of the machine learning model, the type or composition of the metal powder is not input. Instead, the properties of the metal powder, the process conditions, and the relative density powder are trained.

Moreover, a gradient boosting model may be used as an example of a machine learning model in the present invention.

Referring again to FIG. 1, after training the machine learning model, the process conditions with a high relative density for a specific powder are predicted using the machine learning model and a random search (S200).

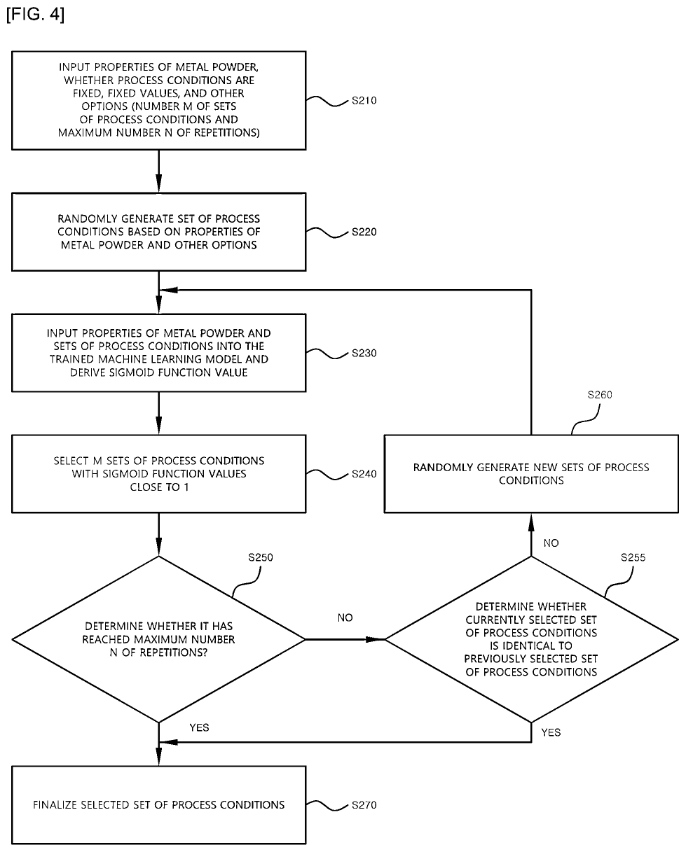

FIG. 4 is a flowchart illustrating a method of predicting process conditions with a high relative density for a specific powder of FIG. 1 according to a preferred embodiment of the present invention.

Referring to FIG. 4, the properties of a metal powder, whether the process conditions are fixed, fixed values, and other options may be input from the user (S210).

The properties of the metal powder may include its thermal conductivity, specific heat capacity, reflectance, mass density, and melting point, and the reflectance can be derived based on the input composition. For example, if the composition formula of the metal powder input by the user is AₐBₐC_{c}, the reflectance of the metal powder follows Equation 4 below:

$$R ( \% ) = [ ( a \times {R}_{A} ) + ( b \times {R}_{B} ) + ( c \times {R}_{C} ) ] \qquad [ Equation 4 ]$$

In Equation 4, R represents the reflectance of the input metal powder, and a, b, and c represent the fractions of elements A, B, and C, respectively. R_{A} represents the reflectance (%) of element A, R_{B} represents the reflectance (%) of element B, and R_{C} represents the reflectance (%) of element C.

The reason the reflectance is derived using Equation 4 is that the reflectance of a physical material in an alloy state can be measured differently depending on the surface state. Therefore, by arithmetically calculating the fractions of the constituent elements constituting the alloy and the reflectance of the elements, it is possible to improve the reliability of the data. Furthermore, during the collection of information, the reflectance of various metal powders may be partially omitted, and thus Equation 4 above can be used to supplement this.

The process conditions can be fixed by machine learning within a range where training data exists. For example, the laser power can range from 50 W to 400 W, the scan speed can range from 100 mm/s to 4500 mm/s, the layer thickness can range from 0.025 mm to 0.12 mm, and the hatch distance can range from 0.08 mm to 0.2 mm. In addition, the user can fix the layer thickness of the metal part to be manufactured. Under conditions where the layer thickness is fixed, a plurality of process conditions that can realize the same layer thickness can be derived by searching for different process conditions.

If the user does not fix a specific process condition in a set of process conditions, sets of process conditions within the trained range may be randomly generated in the subsequent process.

Additionally, other options refer to the number M of sets of process conditions, which are calculated by a single prediction, and the maximum number N of repetitions.

Subsequently, based on the input properties of the metal powder and other options, a set of process conditions may be randomly generated (S220).

In the present invention, the set of process conditions refers to a combination of the respective process conditions, such as laser power, scan speed, hatch distance, and layer thickness, and the combination thereof, forms one unit.

The number of sets of process conditions generated through the random search is 2M, which is twice the number desired by the user. In the above step, if there is a fixed value among the process conditions, other process condition values may be randomly generated around the fixed process condition value, and the number of sets of process conditions generated is 2M, which is twice the number of sets of process conditions input by the user.

However, the number of randomly generated sets of process conditions can optionally exceed the limit specified by the user, as long as it remains within the limit. In other words, if the number of sets of process conditions generated through the random search exceeds M, it does not deviate from the spirit of the present invention.

Moreover, the range of searched process conditions may be limited to the range of training data available through machine learning.

Next, the input properties of the metal powder and the generated sets of process conditions may be input into the trained machine learning model, and the sigmoid function value may be calculated (S230).

The sigmoid function value represents the transformed value of the relative density of the metal part, where a value closer to 1 indicates a higher relative density.

To be input into the machine learning model, the properties of the metal powder input by the user and the randomly generated sets of process conditions may be normalized using the mean and standard deviation used in the normalization process of the machine learning stage, and then input into the model.

Subsequently, similar sets of process conditions may be removed, and M sets of process conditions with sigmoid function values close to 1 may be selected from the input sets of process conditions (S240).

That is, if the sum of differences between the normalized sets of process conditions is less than the difference reference value m, where m is a specific real number, the sets of process conditions with small relative densities, which are the output values of the model and transformed to the sigmoid function values, are removed. The determination of the difference values between the normalized sets of process conditions follows Equation 5 below:

$$\sum \vert {a}_{i} - {b}_{i} \vert < m \qquad [ Equation 5 ]$$

In Equation 5, aᵢ represents the normalized process conditions of process set A, and bi represents the normalized process conditions of process set B. The difference reference value m may have a relatively large value if the user wants to search for a wide range of process conditions, and it may have a relatively small value if the user wants to search for a narrow range of process conditions.

For example, in the case where the difference reference value m is 1 and the randomly generated process conditions A and B satisfy Equation 5 above, if the sigmoid function value of process condition A is greater than the sigmoid function value of process condition B, then process condition B is deleted.

The above process involves selecting process conditions with high relative densities among similar sets of process conditions and deleting similar sets of process conditions with low relative densities during the prediction process.

After the randomly generated similar sets of process conditions are removed, M sets of process conditions may be selected starting from the sets of process conditions with the highest sigmoid function value, and the remaining sets of process conditions may be removed.

Since the machine learning model has received the properties of the metal powder and the randomly generated sets of process conditions totaling 2M, the process conditions with a sigmoid function value close to 1 can be selected through the above-mentioned process. This enables the selection of M sets of process conditions input by the user.

Next, it is determined whether the random generation of sets of process conditions and the selection of M sets of process conditions have reached the maximum number N of repetitions (S250).

If the random generation of sets of process conditions has not reached the maximum number N of repetitions, then an equal number of new sets of process conditions may be randomly generated to replace the sets of process conditions removed in the above-described removal step (S260).

Since M sets of process conditions have been selected from the input sets of process conditions in the removal step and the remaining sets of process conditions have been removed, the same number of sets of process conditions can be generated and compared.

After the random generation of new sets of process conditions, the process may repeat from steps S230 to S250.

Moreover, if it is determined that the random generation of sets of process conditions and the selection of M sets of process conditions have reached the maximum number N of repetitions, the process may be terminated, and the selected set of process conditions may be chosen as the final selection (S270).

Furthermore, depending on the embodiment, a step (S255) of determining whether the currently selected set of process conditions is identical to the previously selected set of process conditions may be further added after step S250. If it is determined that the currently selected set of process conditions is identical to the previously selected set of process conditions, the process may be terminated, and this set of process conditions may be chosen as the final selection (S270).

Depending on the embodiment, step S255 may be performed prior to step S250.

In other words, if the set of process conditions selected in the current step is identical to the set of process conditions selected in the previous step, the process may be terminated, and the selected set of process conditions may be finalized as the final set of process conditions. If the sets of process conditions are not identical, it is determined whether the random generation of sets of process conditions and the selection of M sets of process conditions have reached the maximum number N of repetitions.

If the maximum number N of iterations has been reached, the procedure may be terminated, and the set of process conditions selected in the current step may be finalized as the final set of process conditions. If the maximum number N of iterations has not been reached, the step of randomly generating new sets of process conditions may be performed.

In addition, depending on the embodiment, the operator may simultaneously perform step S250 and step S255. In other words, if it is determined that the set of process conditions selected in the previous step is identical to the set of process conditions selected in the current step and the number of repetitions have reached the maximum number N of repetitions, the set of process conditions selected in the current step may be finalized as the final set of process conditions. If the maximum number N of repetitions has not been reached, the process may continue with the step of randomly generating new sets of process conditions, and the selection of sets of process conditions may be repeated.

### Example of Training Machine Learning Model

From previous research literature, 2167 process conditions were collected for 49 types of powders. Moreover, in addition to the process conditions, the properties of metal powder and the relative density were also collected from previous research literature.

The collected data, including the process conditions and the properties of the metal powder, were normalized through preprocessing. The relative density data were transformed to sigmoid function values, and then a gradient boosting model was trained. This model is one of the machine learning algorithms.

Shapley Additive Explanation (SHAP) analysis was conducted to uncover the correlation between the process conditions and the properties of the metal powder, which are input values, and the relative density, which is target value. This process involves representing the interaction between the inputs and the target value as SHAP scores and calculating the contribution of each input data to the target value.

Through training, the correlation between the properties of the metal powder, the process conditions, and the relative density were established, and the evaluation resulted in a machine learning model accuracy of 87%.

### Prediction Example 1 of Optimal Process Conditions

In the training example of the machine learning model, optimal process conditions for alloy powders not used in the training are predicted.

The optimal process conditions for stainless steel 316L (STS 316L) powder are predicted. Based on the composition of STS 316L, Fe_{0.6875}Ni_{0.1146}Cr_{0.1833}Mo_{0.0146}, a reflectance of 65.33% is determined. Then, the following parameters are input: reflectance 65.33%; thermal conductivity 21.4 W/mK; specific heat capacity 0.5 J/gK; mass density 8 g/cm³, and melting point 1375° C.

Since the average diameter of the powder is 46 μm, the layer thickness among the process conditions cannot be less than 46 μm. Therefore, the layer thickness is fixed at 50 μm, and other options such as 12 sets of process conditions and the maximum number 100,000 of repetitions are input.

The process of random generation and selection of sets of process conditions are performed, and 12 sets of optimal process conditions are derived through the machine learning model disclosed in the training example. To identify the accuracy of the derived sets of optimal process conditions, the metal parts are manufactured using the derived sets of process conditions, and the relative densities are measured and compared.

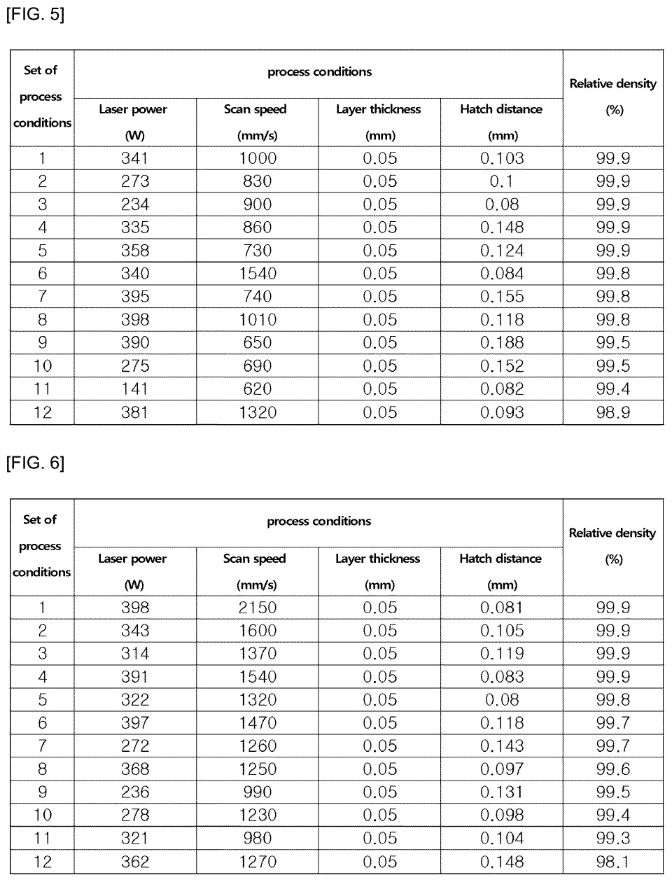

FIG. 5 is a table showing the sets of process conditions predicted in Prediction Example 1 of the present invention and the relative densities measured through experiments.

Referring to FIG. 5, 12 sets of optimal process conditions are presented. The layer thickness is fixed at 50 μm as specified in the input, and the list of sets of process conditions is arranged in the order of sigmoid function values close to 1.

The column marked with Relative Density contains the values obtained by putting the metal powders according to the derived sets of process conditions into the L-PBF equipment, forming the actual alloy layers, and then measuring the relative densities under a microscope. The relative densities show high values exceeding 98%, and it is confirmed that the higher the sigmoid function value, the higher the actual measured relative density. This confirms the accuracy of this machine learning model.

### Prediction Example 2 of Optimal Process Conditions

In the training example of the machine learning model, optimal process conditions for alloy powders not used in the training are predicted.

The optimal process conditions for AlSi₁₀Mg powder are predicted. Based on the composition of metal powder, Al_{0.9045}Si_{0.0916}Mg_{0.0039}, a reflectance of 67.07% is determined. Then, the following parameters are input: reflectance 67.07%; thermal conductivity 146 W/mK; specific heat capacity 0.88 J/gK; mass density 2.67 g/cm³, and melting point 570° C.

Since the average diameter of the powder is set to 46 μm, the layer thickness among the process conditions cannot be less than 46 μm. Therefore, the layer thickness is fixed at 50 μm, and as other options such as 12 of sets of process conditions and the maximum number 100,000 of repetitions are input.

The process of random generation and selection of sets of process conditions are performed, and 12 sets of optimal process conditions are derived through the machine learning model disclosed in the training example. To identify the accuracy of the derived sets of optimal process conditions, the metal parts are manufactured using the derived sets of process conditions, and the relative densities are measured and compared.

FIG. 6 is a table showing the sets of process conditions predicted in Prediction Example 2 of the present invention and the relative densities measured through experiments.

Referring to FIG. 6, 12 sets of optimal process conditions are presented, and the layer thickness is fixed at 50 μm. The various sets of process conditions are arranged in order of high sigmoid function values. The relative density represents the values obtained by applying the derived sets of process conditions to the metal powder and measuring the relative density of samples formed with a thickness of 50 μm.

The measured relative densities show high values of over 98%, and it is confirmed that the higher the sigmoid function value, the higher the relative density in actual samples.

### Prediction Example 3 of Optimal Process Conditions

In the training example of the machine learning model, optimal process conditions for alloy powders not used in the training are predicted.

The optimal process conditions for Fe₆₀Co₁₅Ni₁₅Cr₁₀MEA powder are predicted. Based on the composition of Fe₆₀Co₁₅Ni₁₅Cr₁₀, Fe_{0.6}Co_{0.15}Ni_{0.15}Cr_{0.1}, a reflectance of 66.15% is determined. Then, the following parameters are input: reflectance 66.15%; thermal conductivity 13.66 W/mK; specific heat capacity 0.46 J/gK; mass density 7.91 g/cm³, and melting point 1461.75° C.

Since the average diameter of the powder is 46 μm, the layer thickness among the process conditions cannot be less than 46 μm. Therefore, the layer thickness is fixed at 50 μm, and as other options such as 12 of sets of process conditions and the maximum number 100,000 of repetitions are input.

The process of random generation and selection of sets of process conditions are performed, and 12 sets of optimal process conditions are derived through the machine learning model disclosed in the training example. To identify the accuracy of the derived sets of optimal process conditions, the metal parts are manufactured using the derived sets of process conditions, and the relative densities are measured and compared.

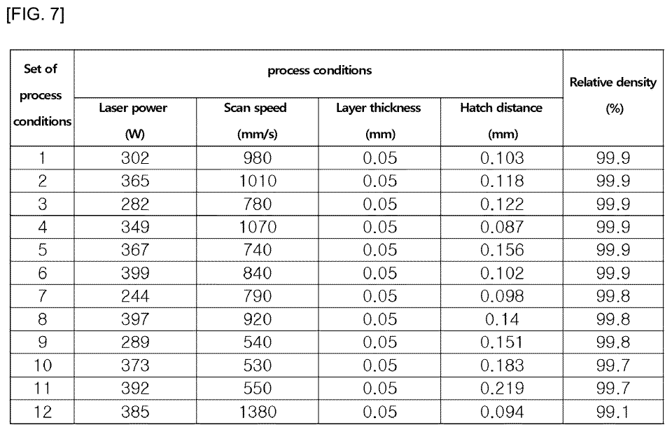

FIG. 7 is a table showing the sets of process conditions predicted in Prediction Example 3 of the present invention and the relative density measured through experiments.

Referring to FIG. 7, 12 sets of process conditions are derived. Similar to other Prediction Examples, the sets of process conditions are sorted in order of high sigmoid function values.

The relative density represents the values obtained by forming 50 μm layers using the derived sets of process conditions and measuring the relative density. It is found that the set of process conditions with a higher sigmoid function value results in a higher measured relative density. This indicates that the machine learning model trained by the present invention achieves high accuracy.

According to the present invention as described above, the properties of the metal powder and the process conditions serve as input data, and the correlation between them and the relative density, which is a target value, is determined through the training of the machine learning model. During this process, the properties of the metal powder and the process conditions are normalized, and the relative density is transformed to a sigmoid function value and used in the training of the machine learning model. Moreover, the user can input the properties of a specific powder that he or she wish to predict, enabling the prediction of process conditions with a high relative density. This allows for the prediction of sets of optimal process conditions even for powders with compositions that were not used in the training of the machine learning model. In other words, the user can input the properties of the powder that he or she wish to use, fixed values of process conditions, etc. to obtain a set of optimal process conditions through the pre-trained machine learning model. This allows for the prediction of sets of optimal process conditions with high relative densities across various alloys, leading to a significant reduction in time and cost spent on optimization for each type of alloy.

While the invention has been shown and described with reference to certain preferred embodiments thereof, it will be understood by those skilled in the art that various changes in form and details may be made therein without departing from the spirit and scope of the invention as defined by the appended claims. Therefore, the scope of the invention is defined not by the detailed description of the invention but by the appended claims, and all differences within the scope will be construed as being included in the present invention.

What is claimed is:

1. A method of predicting optimal process conditions, comprising the steps of:
training a machine learning model based on properties of a metal powder, process conditions, and relative density; and
predicting a set of process conditions with a high relative density for a specific metal powder using the trained machine learning model and random search.

2. The method of predicting optimal process conditions of claim 1, wherein the step of training a machine learning model comprises the steps of:
collecting information consisting of the properties of the metal powder, the process conditions, and the relative density, which are required for the training of the machine learning model;
performing data preprocessing on the collected information; and
training the machine learning model using the preprocessed data.

3. The method of predicting optimal process conditions of claim 2, wherein the step of performing data preprocessing comprises the step of normalizing the properties of the metal powder and the process conditions using mean and standard deviation and converting the relative density to a sigmoid function value.

4. The method of predicting optimal process conditions of claim 3, wherein the sigmoid function value is determined by the following Equation:
$$y = \frac{1}{1 + {e}^{- ( x - {x}_{s t} )}}$$
where y represents the sigmoid function value preprocessed with the sigmoid function for the relative density, x represents the relative density, and xₛₜ represents the reference value of the relative density.

5. The method of predicting optimal process conditions of claim 2, wherein the relative density is measured through image analysis, and the image analysis utilizes area of pores appearing through the cut surface of the metal part.

6. The method of predicting optimal process conditions of claim 2, wherein the properties of the metal powder include reflectance, thermal conductivity, specific heat capacity, melting point, and mass density, and the process conditions include laser power, scan speed, hatch distance, and layer thickness.

7. The method of predicting optimal process conditions of claim 1, wherein the step of predicting a set of process conditions comprises the steps of:
inputting the properties of a metal powder desired by a user, whether the process conditions are fixed, and fixed process condition values;
randomly generating sets of process conditions based on the properties of the metal powder;
deriving a sigmoid function value for each of the randomly generated sets of process conditions by inputting the properties of the metal powder and the randomly generated sets of process conditions into the trained machine learning model; and
selecting sets of process conditions with sigmoid function values close to 1.

8. The method of predicting optimal process conditions of claim 7, wherein the step of inputting the properties of a metal powder desired by a user, whether the process conditions are fixed, and fixed process condition values comprises the step of:
inputting other options such as the number of sets of process conditions to be generated and a maximum number of repetitions.

9. The method of predicting optimal process conditions of claim 8, wherein the number of randomly generated sets of process conditions in the step of randomly generating sets of process conditions exceeds the number of sets of process conditions.

10. The method of predicting optimal process conditions of claim 9, wherein the step of selecting sets of process conditions comprises the steps of:
comparing similar sets of process conditions among the randomly generated sets of process conditions and removing sets of process conditions with low sigmoid function values; and
selecting sets of process conditions with high sigmoid function values from the remaining sets of process conditions after removing the sets of process conditions with the low sigmoid function values.

11. The method of predicting optimal process conditions of claim 8, comprising, after the step of selecting sets of process conditions, the steps of:
determining whether the number of the randomly generated sets of process conditions has reached a maximum number of repetitions; and
if the maximum number of repetitions has not been reached, randomly generating new sets of process conditions.

12. The method of predicting optimal process conditions of claim 11, further comprising the step of:
if the maximum number of repetitions has been reached, finalizing the selected set of process conditions as the final set of process conditions.

13. The method of predicting optimal process conditions of claim 11, further comprising the step of:
after the step of determining whether the number of the randomly generated sets of process conditions has reached the maximum number of repetitions, determining whether the set of process conditions selected in the previous step is identical to the set of process conditions selected in the current step, and
wherein if the two sets of process conditions are identical to each other, the set of process conditions selected in the current step is finalized as the final set of process conditions.

14. A method of predicting optimal process conditions, the method comprising the steps of:
training a machine learning model based on properties of a metal powder, process conditions, and relative density; and
predicting a set of process conditions with a high relative density for a metal powder, which is not used in the training of the machine learning model, using the trained machine learning model and random search.

15. The method of predicting optimal process conditions of claim 14, wherein the step of predicting a set of process conditions comprises the steps of:
inputting the properties of a metal powder not used in the training, whether the process conditions are fixed, the number of sets of process condition, and a maximum number of repetitions;
randomly generating the set of process conditions based on the properties of the metal powder not used in the training, whether the process conditions are fixed, and the number of sets of process condition;
deriving a sigmoid function value for each of the randomly generated sets of process conditions by inputting the properties of the metal powder not used in the training and the randomly generated sets of process conditions into the machine learning model;
selecting the sets of process conditions as many bas the number of sets of process conditions with high sigmoid function values;
determining whether the selection of sets of process conditions has reached the maximum number of repetitions; and
if the maximum number of iterations has been reached, finalizing the selected set of process conditions as the final set of process conditions.

16. The method of predicting optimal process conditions of claim 15, comprising the steps of:
if the selection of sets of process conditions has not reached the maximum number of repetitions, randomly generating new sets of process conditions; and
generating a new sigmoid function by inputting the new sets of process conditions into the machine learning model.

17. The method of predicting optimal process conditions of claim 16, wherein the number of new sets of process conditions is identical to the number of sets of process conditions not selected in the step of selecting sets of process conditions.

18. The method of predicting optimal process conditions of claim 15, wherein the number of randomly generated sets of process conditions is greater than the number of sets of process conditions input by the user.

19. The method of predicting optimal process conditions of claim 15, wherein the step of selecting sets of process conditions comprises the steps of:
comparing similar sets of process conditions among the randomly generated sets of process conditions and selecting sets of process conditions with high sigmoid function values; and
after comparing the similar sets of process conditions, selecting sets of process conditions with high sigmoid function values from the remaining sets of process conditions.

20. The method of predicting optimal process conditions of claim 14, wherein the step of training a machine learning model comprises the steps of:
collecting information consisting of the properties of the metal powder, the process conditions, and the relative density, which are required for the training of the machine learning model;
performing data preprocessing to normalize the properties of the metal powder and the process conditions and convert the relative density to a sigmoid function value; and
training the machine learning model using the preprocessed data.
